(19) United States
(12) Patent Application Publication
(10) Pub. No.: US 2026/0206296 A1
(43) Pub. Date: Jul. 16, 2026

(54) SEMICONDUCTOR DEVICE AND MANUFACTURING METHOD THEREOF

(71) Applicant: Silergy Semiconductor Technology (Hangzhou) LTD, Hangzhou (CN)

(72) Inventors: Chuan Peng, Hangzhou (CN); Gan Thiam Hoe, Hangzhou (CN); Zheng Lv, Hangzhou (CN); Xunyi Song, Hangzhou (CN)

(21) Appl. No.: 19/440,093

(22) Filed: Jan. 5, 2026

(30) Foreign Application Priority Data
Jan. 10, 2025 (CN) 202510046638.7

(51) Int. Cl. H10D 84/00; H10D 1/00; H10D 1/47; H10D 1/68

(52) U.S. Cl. CPC H10D 84/201; H10D 1/021; H10D 1/041; H10D 1/47; H10D 1/68

(57) ABSTRACT

A method of forming a semiconductor device having a metal-insulator-metal (MIM) capacitor and a thin-film resistor, can include: forming a multilayer structure including a lower metal layer, a first dielectric layer located on the lower metal layer, an upper metal layer located on the first dielectric layer, and a solder layer located on the upper metal layer; performing patterned etch on the multilayer structure to form a first structure and a second structure separated from each other; etching part of the solder layer in the second structure to expose part of the upper surface of the upper metal layer, where the remaining solder layer is configured as electrodes of the thin-film resistor; and forming a set of conductive channels respectively correspondingly connected to the first structure and the second structure.

### RELATED APPLICATIONS

This application claims the benefit of Chinese Patent Application No. 202510046638.7, filed on Jan. 10, 2025, which is incorporated herein by reference in its entirety.

### FIELD OF THE INVENTION

The present invention generally relates to the field of semiconductors, and more particularly to semiconductor devices and associated manufacturing methods.

### BACKGROUND

Resistors and capacitors are widely used in analog circuits and basic circuit modules. In some high-precision analog integrated circuits, such as multi-bit digital-to-analog converters, resistors are typically implemented using thin-film resistors with low mismatch, low temperature coefficient of resistance (TCR), and low voltage coefficient of resistance (VCR). Capacitors can be implemented using metal-insulator-metal (MIM) capacitors. An MIM capacitor is equivalent to a parallel-plate capacitor, generally formed by two metal layers with a special thin dielectric layer in between, resulting in high capacitance density. In existing technologies, forming a thin-film resistor and an MIM capacitor are two independent steps. In such an approach, forming the thin-film resistor after forming the MIM capacitor requires two additional lithography and etching processes, the process cost is increased.

### BRIEF DESCRIPTION OF THE DRAWINGS

FIG. 1 is a flow diagram of an example method of forming a semiconductor device, in accordance with embodiments of the present invention.

FIGS. 2A-2E are cross-sectional structural diagrams of certain steps of the example method of forming a semiconductor device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

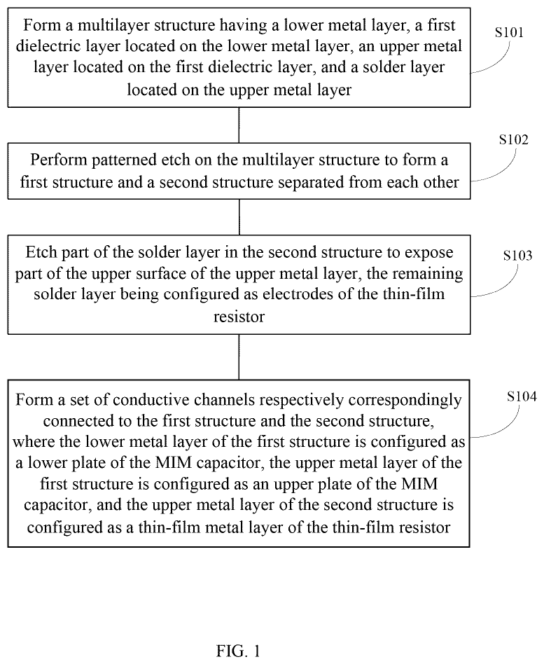

Referring now to FIG. 1, shown is a flow diagram of an example method of forming a semiconductor device, in accordance with embodiments of the present invention. In this particular example, at S101, a multilayer structure can be formed, whereby the multilayer structure can include a lower metal layer, a dielectric layer located on the lower metal layer, an upper metal layer located on dielectric layer, and a solder layer located on the upper metal layer.

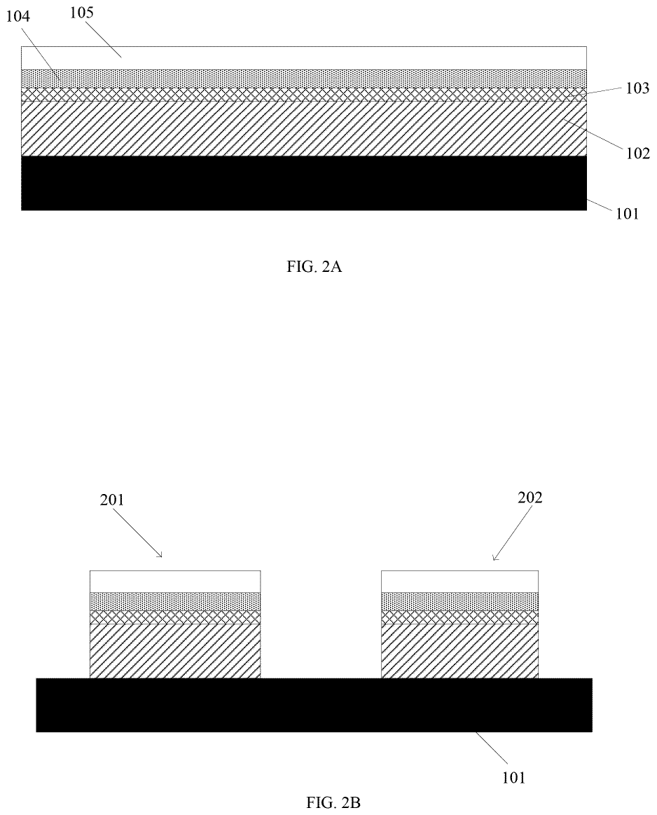

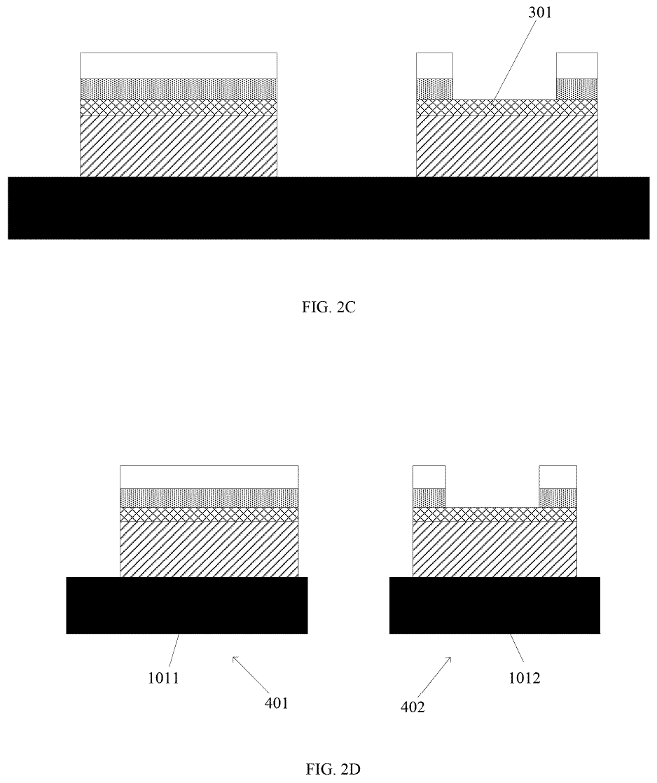

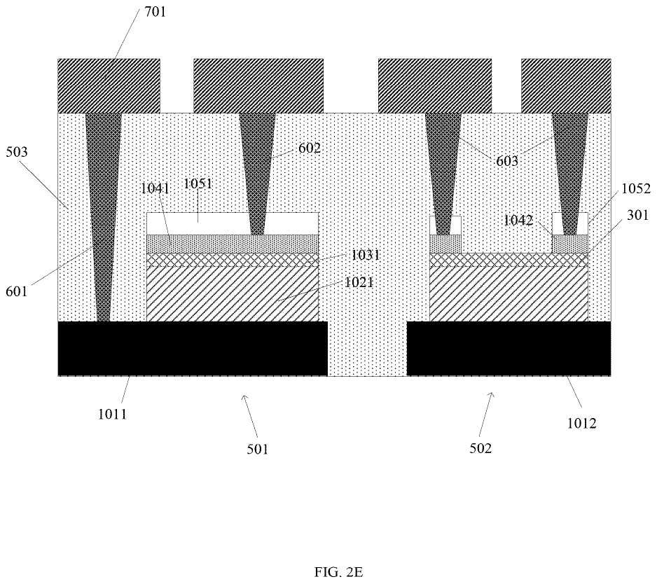

Referring also to FIGS. 2A-2E, shown are cross-sectional structural diagrams of certain steps of the example method of forming a semiconductor device, in accordance with embodiments of the present invention. As shown in FIG. 2A, lower metal layer 101 can be formed, then dielectric layer 102 can be formed on lower metal layer 101, upper metal layer 103 can be formed on dielectric layer 102, and solder layer 104 can be formed on upper metal layer 103. For example, lower metal layer 101 can be an aluminum layer, and may serve as the lower plate of the MIM capacitor. For example, dielectric layer 102 can include at least one of: an oxide layer, a nitride layer, and another insulating layer.

In particular embodiments, dielectric layer 102 can be arranged between the upper plate and lower plate of the MIM capacitor. Upper metal layer 103 may serve as the upper plate of the MIM capacitor and as the thin-film metal layer of the thin-film resistor in subsequent processes. For example, upper metal layer 103 can be made of CrSi material, but can also be made from other metal materials, such as SiCCr, TaN, NiCr, AlNiCr, TiNiCr, etc., or any other suitable thin-film resistor material or a combination thereof. Solder layer 104 can serve as a via stop layer for the subsequent thin-film resistor. The metal layer (e.g., upper metal layer) of the thin-film resistor can be relatively thin, and can in some cases be penetrated during via formation process. Therefore, a barrier layer can be formed thereon to function both as the solder layer for the thin-film resistor, and to protect the surface of the thin-film resistor from damage. In this example, the solder layer can be made of titanium nitride.

In particular embodiments, the multilayer structure can also include protective layer 105 located on solder layer 104. For example, protective layer 105 can be made of silicon oxynitride. The lower metal layer can be any metal layer from the first metal layer to the penultimate top metal layer in the semiconductor integrated circuit or device manufacturing process. At S102 of FIG. 1, a patterned etch can be performed on the multilayer structure to form first and second structures that are separated from each other.

For example, S102 can also include the following two steps. As shown in FIG. 2B, using a patterned photoresist as a mask, an etch can be performed downward from the upper surface of the multilayer structure and stopped at the upper surface of lower metal layer 101. For example, a first photoresist layer can be formed on the multilayer structure, the first photoresist layer can be patterned through exposure and development, and the patterned first photoresist layer can be used as a mask to perform reactive ion etching on the multilayer structure. This process can form portions 201 and 202 with lower metal layer 101 as a common bottom, where portion 201 corresponds to the MIM capacitor structure part, and portion 202 corresponds to the thin-film resistor structure part. Portions 201 and 202 can be separated from each other on lower metal layer 101. Further, the structure on the two side edges of lower metal layer 101 may also be etched, e.g., the upper surfaces of the two side edges of lower metal layer 101 can also be exposed.

In the second step of S102, etching the lower metal layer can be continued to form first and second structures separated from each other. Examples of these steps are shown in FIG. 2D and will be described further below. At S103, part of the solder layer in the second structure can be etched, in order to expose part of the upper surface of the upper metal layer. The remaining solder layer may serve as the electrode of the thin-film resistor.

As shown in FIG. 2C, in the example structure including protective layer 105, by using a patterned third photoresist as a mask, part of the protective layer and solder layer of portion 202 can be etched to expose part of the upper surface of the upper metal layer. For example, a layer of photoresist layer may be formed on the structure shown in FIG. 2B. Performing exposing and developing on the photoresist layer can be used to form a patterned third photoresist, and using the patterned third photoresist as a mask, protective layer 105 can be etched using a dry etching process to form a patterned protective layer.

Then, a wet etching process can be performed to etch solder layer 104 and expose part of the upper surface of the upper metal layer. In this example, the upper metal layer of portion 202 can be configured as thin-film metal layer 301 of the thin-film resistor. In other examples, a dry etching process can also be used to directly etch the protective layer and solder layer, in order to expose part of the upper surface of the upper metal layer. Any suitable process method for etching the protective layer and solder layer can be employed in certain embodiments.

As shown in FIG. 2D, etching the lower metal layer to form first structure and second structure separated from each other. For example, a patterned second photoresist can be formed on the structure of FIG. 2C, and the patterned second photoresist can be used as a mask for etching the lower metal layer to form two separated parts 1011 and 1012. Structure 401 can include lower metal layer part 1011 and portion 201 located thereon. Structure 402 can include lower metal layer part 1012 and portion 202 located thereon. The upper surface of at least one side of lower metal layer part 1011 can be exposed by portion 201.

The distance between lower metal layer parts 1011 and 1012 (e.g., the etching window of the second photoresist) can be less than the distance between portion 201 and portion 202. In this example, the upper surfaces of both sides of lower metal layer part 1011 can be exposed by portion 201, and the upper surfaces of both sides of lower metal layer part 1012 may be exposed by portion 202.

In addition, the process steps of FIGS. 2C and 2D can be interchanged without affecting the final structural diagram. That is, in some cases the step of etching lower metal layer in FIG. 2D can be performed first, and then the step of etching the protective layer and solder layer of portion 202 in FIG. 2C can be performed. At S104 of FIG. 1, a set of conductive channels can be formed, respectively, and correspondingly connected to structure 401 and structure 402.

As shown in FIG. 2E, interlayer dielectric layer 503 covering structure 401 and structure 402 can be formed, whereby interlayer dielectric layer 503 is further located between structures 401 and 402 to isolate them. Interlayer dielectric layer 503 can be etched by laser etching or reactive ion etching to form first vias connecting to structure 401 and second vias connecting to structure 402. Subsequently, conductive material can be filled into the first and second vias to form “first” conductive channels 601 and 602 and “second” conductive channels 603. Conductive channel 601 may extend from the upper surface of interlayer dielectric layer 503, through interlayer dielectric layer 503, to the upper surface of lower metal layer 1011 of structure 401. Conductive channel 602 may extend from the upper surface of interlayer dielectric layer 503, through interlayer dielectric layer 503 and protective layer 1051 of structure 401, to the upper surface of solder layer 1041 of structure 401. Conductive channel 603 may extend from the upper surface of interlayer dielectric layer 503, through the interlayer dielectric layer and the protective layer 1052 of structure 402, to the upper surface of solder layer 1042 of structure 402.

The method can also include forming mutually separated multiple metal layers 701. Metal layers 701 may be in contact with the upper surfaces of the conductive channels, where each conductive channel can connect to corresponding metal layer 701. Here, lower metal layer 101 can be configured as the second-level metal layer in the semiconductor integrated circuit or device manufacturing process, and metal layers 701 can be configured as the third-level metal layer in the semiconductor integrated circuit or device manufacturing process.

In particular embodiments, a method of simultaneously manufacturing an MIM capacitor and a thin-film resistor can be provided. Using only two lithography and etching processes (e.g., the first etching process defines the MIM capacitor region and thin-film resistor region, the second etching process defines the specific structure of the thin-film resistor), the MIM capacitor structure and thin-film resistor structure can be manufactured. As compared to traditional methods, the approach of certain embodiments may reduce one lithography and etching process, and as such the overall process cost can be reduced.

Particular embodiments may also provide a semiconductor device, as shown in FIG. 2E, and formed according to the aforementioned method. The semiconductor device can include metal-insulator-metal (MIM) capacitor 501 and thin-film resistor 502. MIM capacitor 501 can include lower metal layer 1011, upper metal layer 1031, dielectric layer 1021 located between upper metal layer 1031 and lower metal layer 1011, and solder layer 1041 located on upper metal layer 1031. Further, MIM capacitor 501 can also include protective layer 1051 located on solder layer 1041.

Thin-film resistor 502 can include thin-film metal layer 301 and solder layer 1042 located on thin-film metal layer 301, whereby an opening of which can expose an upper surface of thin-film metal layer 301. As such, solder layer 1042 can include an opening exposing the upper surface of the thin-film resistor metal layer. Further, thin-film resistor 502 can also include protective layer 1052 located on solder layer 1042. Protective layer 1052 may have an opening of the same width as solder layer 1042, whereby part of the upper surface of the thin-film metal layer 301 can be exposed by solder layer 1042 and protective layer 1052.

The semiconductor device can also include a dummy dielectric layer and dummy lower metal layer 1012. Thin-film resistor metal layer 301 and upper metal layer 1031 can be same level metal layers and separated from each other. The dummy dielectric layer and dielectric layer 1021 may be same level dielectric layers and separated from each other, and dummy lower metal layer 1012 and lower metal layer 1011 can be the same level metal layers and separated from each other. Solder layers 1041 and 1042 can be located at the same level and separated from each other. Protective layers 1051 and 1052 can be located at the same level and separated from each other. For example, upper metal layer 1031 and thin-film metal layer 301 can be CrSi material, but can also be other metal materials, such as SiCCr, TaN, NiCr, AlNiCr, TiNiCr, etc., or any other suitable thin-film resistor material or a combination thereof.

Solder layer 104 may serve as a via stop layer for the subsequent thin-film resistor. The metal layer (e.g., upper metal layer) of the thin-film resistor can be relatively thin and may be penetrated during via formation process in some cases. Therefore, forming a barrier layer thereon can function both as the solder layer for the thin-film resistor and may protect the surface of the thin-film resistor from damage. In this particular example, solder layers 1041 and 1042 can be made of titanium nitride.

A width of dielectric layer 1021 of the MIM capacitor can be less than the width of lower metal layer 1011, in order to expose portion of the upper surface of at least one side of lower metal layer 1011. Dielectric layer 1021 and upper metal layer of the MIM capacitor can be justified in vertical alignment. The semiconductor device can also include interlayer dielectric layer 503, in which both MIM capacitor 501 and thin-film resistor 502 may be formed.

The MIM capacitor can include conductive channel 601 extending from the upper surface of interlayer dielectric layer 503, through interlayer dielectric layer 503, to the upper surface of lower metal layer 1011, and conductive channel 602 extending from the upper surface of interlayer dielectric layer 503, through the interlayer dielectric layer and protective layer 1051 of the MIM capacitor, and to the upper surface of solder layer 1041 of the MIM capacitor. The thin-film resistor can include at least two conductive channels 603 extending from the upper surface of interlayer dielectric layer 503, through the interlayer dielectric layer and protective layer 1052 of the thin-film resistor, and to the upper surface of solder layer 1042 of the thin-film resistor. The semiconductor device can also include mutually separated multiple metal layers 701. Metal layers 701 can be in contact with the upper surfaces of the conductive channels, whereby each conductive channel can be configured to connect to corresponding metal layers 701.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of forming a semiconductor device having a metal-insulator-metal (MIM) capacitor and a thin-film resistor, the method comprising:
a) forming a multilayer structure comprising a lower metal layer, a first dielectric layer located on the lower metal layer, an upper metal layer located on the first dielectric layer, and a solder layer located on the upper metal layer;
b) performing patterned etch on the multilayer structure to form a first structure and a second structure separated from each other;
c) etching part of the solder layer in the second structure to expose part of the upper surface of the upper metal layer, wherein the remaining solder layer is configured as electrodes of the thin-film resistor;
d) forming a set of conductive channels respectively correspondingly connected to the first structure and the second structure; and
e) wherein the lower metal layer of the first structure is configured as a lower plate of the MIM capacitor, the upper metal layer of the first structure is configured as an upper plate of the MIM capacitor, and the upper metal layer of the second structure is configured as a thin-film metal layer of the thin-film resistor.

2. The method of claim 1, wherein forming the first structure and the second structure comprises:
a) forming a patterned first photoresist on an upper surface of the multilayer structure;
b) etching from the upper surface of the multilayer structure and stop at the upper surface of the lower metal layer, using the patterned first photoresist as a mask, to form a first portion and a second portion with lower metal layer as common bottom;
c) forming a patterned second photoresist on the etched multilayer structure; and
d) etching the lower metal layer, using the patterned second photoresist as a mask, to form the first structure comprising the first portion and the second structure comprising the second portion.

3. The method of claim 2, wherein a width of an etching window of the second photoresist is less than a distance between the first portion and the second portion.

4. The method of claim 1, wherein performing patterned etch on the multilayer structure to expose an upper surface of at least one side of the lower metal layer of the first structure.

5. The method of claim 1, wherein the multilayer structure further comprises a protective layer formed on an upper surface of the solder layer.

6. The method of claim 1, wherein a wet etching process is used to etch the solder layer in the second structure.

7. The method of claim 5, wherein before etching part of the solder layer in the second structure, the method further comprises a dry etching process being used to etch the protective layer.

8. The method of claim 1, wherein before forming the conductive channels, the method comprises forming an interlayer dielectric layer covering the first structure and the second structure.

9. The method of claim 8, wherein forming the conductive channels comprises:
a) forming a first set of vias connecting to the first structure and a second set of vias connecting to the second structure, wherein one first via extends from the upper surface of the interlayer dielectric layer to the solder layer of the first structure, the other first via hole extends from the upper surface of the interlayer dielectric layer, through the interlayer dielectric layer, to the lower metal layer of the first structure, and two second vias respectively extend from the upper surface of the interlayer dielectric layer to the electrodes of the thin-film resistor; and
b) filling the first set of vias and the second set of vias with conductive material to form conductive channels.

10. A semiconductor device, comprising:
a) a metal-insulator-metal (MIM) capacitor, comprising a lower metal layer, an upper metal layer, a first dielectric layer located between the upper metal layer and the lower metal layer, and a first solder layer located on the upper metal layer;
b) a thin-film resistor, comprising a thin-film metal layer and a second solder layer located on the thin-film metal layer, an opening of which is included to expose an upper surface of the thin-film metal layer;
c) a dummy dielectric layer located below the thin-film metal layer;
d) a dummy metal layer located below the dummy dielectric layer; and
e) wherein the thin-film metal layer and the upper metal layer are same level metal layers and separated from each other, the dummy dielectric layer and the first dielectric layer are same level dielectric layer and separated from each other, and the dummy metal layer and the lower metal layer are same level metal layers and separated from each other.

11. The semiconductor device of claim 10, wherein a width of the first dielectric layer is less than a width of the lower metal layer of the MIM capacitor to expose portion of the upper surface of at least of one side of the lower metal layer.

12. The semiconductor device of claim 10, wherein the first dielectric layer and the upper metal layer of the MIM capacitor are justified.

13. The semiconductor device of claim 10, wherein the MIM capacitor further comprises a first protective layer located on the first solder layer, and the thin-film resistor further comprises a second protective layer separated from the first protective layer located on the second solder layer.

14. The semiconductor device of claim 10, further comprises an interlayer dielectric layer, in which both the MIM capacitor and the thin-film resistor are formed.

15. The semiconductor device of claim 14, wherein the MIM capacitor comprises:
a) a first conductive channel extending from the upper surface of the interlayer dielectric layer to the upper surface of the lower metal layer, and a second conductive channel extending from the upper surface of the interlayer dielectric layer to the upper surface of the first solder layer of the MIM capacitor; and
b) the thin-film resistor comprises at least two third conductive channels extending from the upper surface of the interlayer dielectric layer to the upper surface of the second solder layer of the thin-film resistor.

16. The semiconductor device of claim 15, wherein the semiconductor device further comprises a plurality of mutually separated second metal layers, the plurality of second metal layers respectively contacting the upper surfaces of the first conductive channel, the second conductive channel, and the third conductive channels.

17. The semiconductor device of claim 10, wherein a material of the thin-film metal layer and the upper metal layer comprise at least one of: CrSi, SiCCr, TaN, NiCr, AlNiCr and TiNiCr.

18. The semiconductor device of claim 10, wherein a material of the solder layer comprises TiN material.
